(19) United States
(12) Patent Application Publication
(10) Pub. No.: US 2006/0196917 A1
(43) Pub. Date: Sep. 7, 2006

(54) METALLIC PLATING FOR SOCKET APPLICATION IN BALL GRID ARRAY PACKAGES

(75) Inventors: Giorgio Viero, Stezzano (BG) (IT); Stefano Sergio Oggioni, Milano (IT); Michele Castriotta, Manfredonia (IT)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/164,719

(22) Filed: Dec. 2, 2005

(30) Foreign Application Priority Data
Dec. 2, 2004 (EP) 04106240.7

(51) Int. Cl. B23K 1/20; B23K 31/02

(52) U.S. Cl. 228/208

(57) ABSTRACT

A method for partially plating balls for application in ball grid array packages is disclosed. The balls are positioned in recesses of a clam tool made of two parts, such that a gap remains between these parts. A first polymer layer is formed in this gap and one part of the clam tool is thereafter removed. The resulting exposed portions of the balls are covered with a second polymer. The second part of the clam tool is removed and the resulting second exposed portions of the balls are plated with a noble metal, such as gold or palladium. After the balls have been partially plated, the second polymer is removed, leaving the partially plated balls embedded in the first polymer layer. The first polymer layer, preferably a soft foil, may be used to position the partially plated balls for attachment to an electronic module.

### FIELD OF THE INVENTION

The present invention relates generally to electronic packages and more specifically to a method for improving metallic plating of balls in ball grid array packages for establishing reliable electrical connections between electronic packages and printed circuit boards.

### BACKGROUND OF THE INVENTION

Plastic Ball Grid Array (PBGA) module, with low-melt alloy balls, represents an evolution of electronic modules from the classical ceramic substrate. Historically, ceramic carriers use arrays of pins plated with Gold for mounting into sockets. These pins are then inserted into sockets that have mating surfaces also plated with Gold. Good contacts are realized by the utilization of spring loaded or clamping mechanisms.

The new industry trend of using cheaper materials lead to the use of Input/Output technologies that are based upon matrix of balls made of soldering alloys for transmitting electrical signal between electronic modules and Printed Circuit Boards (PCBs). This generates a migration away from sockets toward direct soldering. This interconnection technique is also called Solder Ball Connection (SBC).

These new Input/Output technologies are extensively implemented in low cost applications from consumer electronics to personal computers, and are rapidly moving toward the high end computing sector. However, in this specific market segment, particular requirements need to be met, like the necessity of component field replacement and upgradeability as well as the module level Burn-In testing. This was done in the past with the Pin Grid Array (PGA) packages having Gold plated pins inserted in Gold plated socket receptacles, and later using Land Grid Array (LGA) technology, where the pins where removed, leaving a Gold plated pad pressed against a similar metalized pad (Pad on Pad) on the PCB through an anisotropic conductive elastomer. But this is now becoming an unaffordable cost and technically difficult for organic substrates that are relatively softer than ceramic carriers, and cannot withstand the amount of pressure required to obtain a low ohmic contact resistance values. Furthermore, microprocessors and complex Application Specific Integrated Circuit (ASICS) are growing in size and the associated costs for PGA or LGA solutions for large body sizes are becoming prohibitive in their manufacturing costs and mostly in their implementation into products. SBC-like packaging is now being considered for microprocessors and lack of pluggability remains a major hurdle to use this technology.

Electronic modules generally use a rigid (plastic, ceramic) or flexible (polyimide) substrates that are then attached, usually by soldering techniques, to electronic circuits embedded into PCB substrates.

Soldering technology implies a higher level of complexity for the part replacement, which can be accomplished only by the usage of industrial processes (desoldering, cleaning, and soldering of new component), while the positioning of a module into sockets allows the replacement of the same in the field without the need of special processes, maybe requiring just a mechanical extractor tool.

On the other hand, the soft nature of the BGA ball materials require handling procedures and special probes characteristics to manage the level of penetration of the latter into the solder alloy bulk. Furthermore, soldering alloys contain metals like Tin, Copper, Silver, Indium, Bismuth and Zinc that are easily oxidizing when exposed to air and temperature excursions. Oxide layers prevent good electrical contacts between module and socket pins unless the socket contact probes are designed to break the oxide layer but, even in this case, this is just a temporary solution due to the unavoidable oxidation of the newly exposed material in due time. Oxidation of contacts leads to an increasing contact resistance drift that ultimately will generate intermittent/full electrical failures of the module and consequently in the systems.

In IBM Technical Disclosure Bulletin, the publication referred to as AT 885-0235 (September, 1986) discloses the use of a copper ball surrounded by eutectic solder as the joint structure for attaching a MultiLayer Ceramic (MLC) substrate to a PCB laminate wherein the ball serves as standoff. A similar concept is described by Totta and Sopher for SLT technology, as described in “SLT Device Metallurgy and its Monolithic Extensions” IBM JRD, Vol 13, No. 3, pages 226-238, May 1969. Both techniques employ soldering together of two distinct components.

Japanese patent No. 7,099,385 describes a manufacturing process for preventing crushing of an entire solder ball due to melting of solder and provides a simple connection structure in the gap between connection terminals by using a metallic sphere precoated with solder.

The basic SBC structure and processes are described in U.S. Pat. Nos. 5,060,844 and 5,118,027, which patents are hereby incorporated by reference.

Bearing in mind the problems and deficiencies of the prior art, there is a need to use solder ball connector technology to make electronic components having shaped socketable solder bump grid arrays for electrically connecting the electronic component to another electronic component.

U.S. Pat. No. 6,168,976 discloses socketable balls that are mounted to a BGA package by first placing the balls into a pockets or holes of a tray that are sized such that when the balls are inserted, an upper portion of the ball protrudes above a planar surface of the tray. A layer of polymer is then applied over the balls and a top area of each of the balls is exposed, and coated with solder. During the plating step the polymer provides a solder-tight seal against each of the balls such that, except for the top area, the rest of the surface area of the balls remains solder-free. The solder-plated top area of each of the balls is then soldered to the corresponding plurality of lands of the package by reflowing the solder to establish electrical contact therebetween.

In the case of usage of copper balls, the finishing by a noble plated metal, compatible with the gold finishing of the socket leads, provides a possible suitable solution to the drawbacks caused by the oxidation effects associated with tin based alloy materials.

Such a possible solution would address the socket compatibility problem with the plating of Copper spheres with Gold, but such a solution also implies a level of process control to maintain the level of solder joint embrittlement in the BGA attachment process to the substrate.

Socketing and the late utilization of anisotropic conductive elastomers in place of standard sockets, require the electronic modules to have a reliable noble metal surface to be contacted, this translates into plating thickness i.e. for the module spheres. A standard plating thickness requirement is to have at least 0.6 lm Au (suggested minimum thickness) with higher thicknesses up to 1 lm for products requiring higher contacts reliability and extended life time.

The above minimum Au thickness requirement removes the possibility of using plating processes known to deliver just a thin Au layer (0.06 to 0.1 lm) over a diffusion Ni barrier of a few lm (generally from 4 to 6 lm). Such plating processes use a chemistry with an auto-catalytic reaction creates a gold layer on top of the plated nickel layer, where mechanistic study have determined that the last layer of nickel atoms are being replaced by atoms of gold. This is a self limited reaction and does not allow growing thicker gold layers and it is porous in nature. Such chemistries known as ENiG (Electroless Nickel Gold) and Au flash plating have a limited acceptability due to the high variability of results in the mechanical strength of the Ni—Sn intermetallic formation. Electroless plated Nickel from Ni—P baths have demonstrated fragility due to segregated Phosporous entrapped into the Ni layer. Furthermore these electroless baths are one of the base metallurgy to grow thicker Au layers required to meet the socketing requirements. Other options will be to use electrolityc plating that requires an electrical commoning of all the metal features that need to be plated.

During the soldering operation the molten solder dissolves the metallization and/or the base contact metal and precipitate intermetallics that will form the bond responsible for giving the solder joint its strength. If the metallization dissolves too rapidly or if it is too thick, the integrity of the solder joint can be compromised by forming a too large volume fraction of the intermetallic phase. To control the amount of intermetallic in a solder joint it is necessary to understand the dissolution rates and phase equilibria controlling the process.

If the gold concentrations in a tin based solder alloy is too high, an embrittlement level of the solder joint will occur due to precipitation of intermetallic AuSn₄. The phase equilibrium between tin-lead-gold is an important tool that can be used to understand and design more reliable solder joints and component contact metallizations. For example, when eutectic tin/lead solder is reflowed in contact with the Au/Ni metallization layers, the Au quickly (1 mm/sec) dissolves into the solder and forms a distribution of AuSn₄, a long, brittle structure, throughout the solder, once the Au is dissolved, then tin also starts to react with nickel forming tin-nickel intermetallic as well.

If the Gold concentrations in tin-lead solder reach a too high level, embrittlement of the solder joint will occur, which can lead to a significant reduction in the fatigue life of the solder joints. It is commonly accepted that gold embrittlement will not occur with less than 3% in weight. One way to reduce this problem is by keeping the gold thickness to a minimum. In situations where thick Au deposits (>0.5 lm) are present, the large quantity of AuSn₄ that forms usually segregates and cannot disperse uniformly through the solder connection. The elevated concentrations of Au in the areas of segregation greatly degrade the integrity of the solder connections, especially where cyclic thermal environments are encountered in service.

Recent research also has shown that after aging at 150° C. for as little as 3 hours the AuSn₄, in the bulk of the solder, redeposited at the solder/Ni₃Sn₄ interface and forms a new ternary Au—Ni—Sn intermetallic compound that grows into a new layer that has detrimental effects on the joint reliability. The aged joints were found to be significantly weaker than the same joints tested before aging. Solid state diffusion (scavenging) occurs when a gold surface has been left in contact with tin. Over time and temperature the gold will dissolve into the solder, leaving a void that causes the solder joint to fracture. Kirkendall porosity occurs when the diffusing rates of two or more elements are not the same. When one element diffuses faster than the others, vacancies are formed in the material with the higher diffusion rate. The vacancies accumulate to form a line of voids that severely diminishes mechanical stability.

If lead is present, the intermetallics that are formed from gold and tin will embrittle the solder joint. This is due to the precipitation of the gold intermetallic along the lead grain boundaries forming intermetallic crystals.

Finally, the full plating solution become very expensive and difficult to be maintained in a high volume production manufacturing line and across the whole supply chain. Too many parameters are required to be controlled to avoid dramatic domino effects in the field due to the joint fragility that increases with time.

### SUMMARY OF THE INVENTION

Thus, it is a broad object of the invention to remedy the shortcomings of the prior art as described here above.

It is another object of the invention to provide a method for half plating balls with noble metal.

It is a further object of the invention to provide a method for half plating balls with noble metal and embedding these balls in soft foils, these balls being all oriented according to the same direction.

The accomplishment of these and other related objects is achieved by a method for partially plating at least one ball, the method comprising the steps of:

providing a clam tool comprising two parts, each part comprising a respective recess configured to cover a portion of said ball wherein if said respective recesses of said two parts are aligned to form a cavity, the size of said cavity is such that when said ball is positioned within said cavity a gap is formed between said two parts;

positioning said ball in said cavity;

forming a first polymerized polymer in said;

removing one of said two parts to expose a first uncovered part of said ball;

covering said first uncovered part of said ball with a second polymerized polymer;

removing the second one of said two parts to expose a second uncovered part of said ball; and

plating said second uncovered part of said ball.

Further advantages of the present invention will become apparent to the ones skilled in the art upon examination of the drawings and detailed description. It is intended that any additional advantages be incorporated herein.

### BRIEF DESCRIPTION OF THE DRAWINGS

FIG. 1 shows an half plated ball adapted to be mounted on a socketable Ball Grid Array packages, according to the invention.

FIG. 2 illustrates a section view of a socketable Ball Grid Array package comprising half coated balls, according to the invention

FIG. 3 depicts an example of the main steps of the method of the invention to manufacture half coated balls.

FIG. 4 , comprising FIG. 4a to 4h, depicts the main states of a ball when being half plated according to the method illustrated on FIG. 3.

FIG. 5 shows how the soft foil embedding oriented half plated balls can be used to position the balls on the electronic modules.

FIG. 6 illustrates an example of pre-cut portions of soft foil embedding oriented half plated balls, obtained from a tape feeding reel.

### DETAILED DESCRIPTION OF THE PREFERRED EMBODIMENT

The main concept of this invention consists in providing a semi-plated or half plated Copper sphere that is compatible with the contact surface requirements of sockets e.g., Gold to Gold dry contact, on one side of the sphere and a reliable soldering surface e.g., a soldering surface protected against the formation of Gold/Tin and Tin/Nickel intermetallics, and offering the standard and proven reliable soldering system interface on the other side e.g., Copper/Tin interface. An example of such half plated sphere or ball is illustrated on FIG. 1 . As shown, the ball 100 comprises a first part 105 plated with a first material adapted for soldering operation and a second part 110 plated with a second material, preferably a noble metal, adapted for establishing reliable solderless electrical contact. In a preferred embodiment, ball 100 is made of Copper or is fully or partially plated with Copper (105) that is adapted for soldering operation and half plated with Nickel-Gold (110).

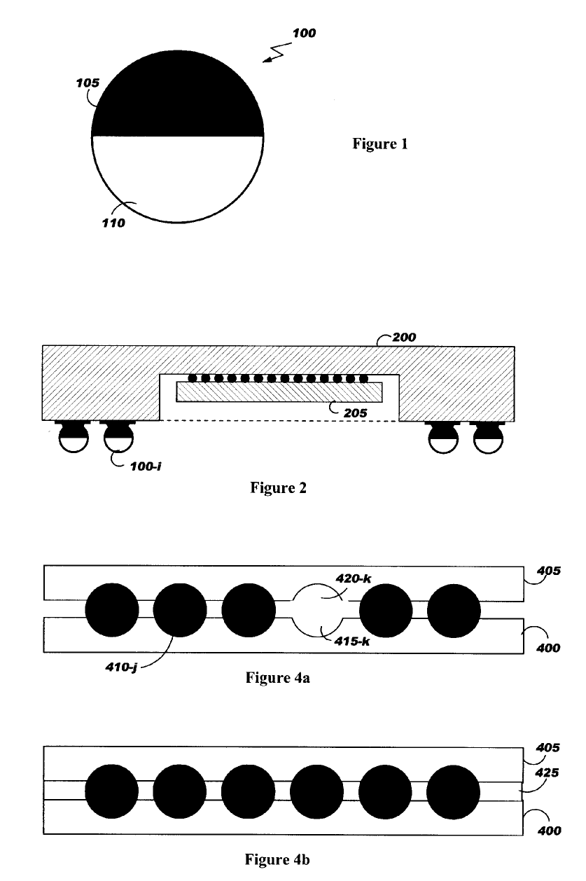

FIG. 2 illustrates a Ball Grid Array (BGA) module 200 comprising a cavity adapted for receiving a semiconductor chip 205 that can be mounted according to flip-chip technology as illustrated. BGA module 200 comprises several half plated balls, generically referred to as 100-i, that are soldered to the module using the Copper plated part. As shown, the half plated balls are positioned on the module in such a way that the parts plated with noble metal are in contact with the receiving Input/Output of the socket when the module is inserted therein.

In a preferred embodiment the balls are attached to the organic package with a process that makes them fully compatible with the set of tools and equipment currently available in the manufacturing lines. The basic copper balls have preferably common dimensions, according to the current industry standard requirements, compatible with the interconnect pitch and socket. As mentioned above, the Copper balls are also partially plated with a Nickel metal layer, before the plating finishing, that is the pre-treatment required for the finishing with a noble metal, such as Gold or Palladium, based on standard processes. However, this plating of Nickel layer can be avoided with the use of new technology offering a Gold finishing directly on Copper, avoiding the intermediate Nickel deposition step.

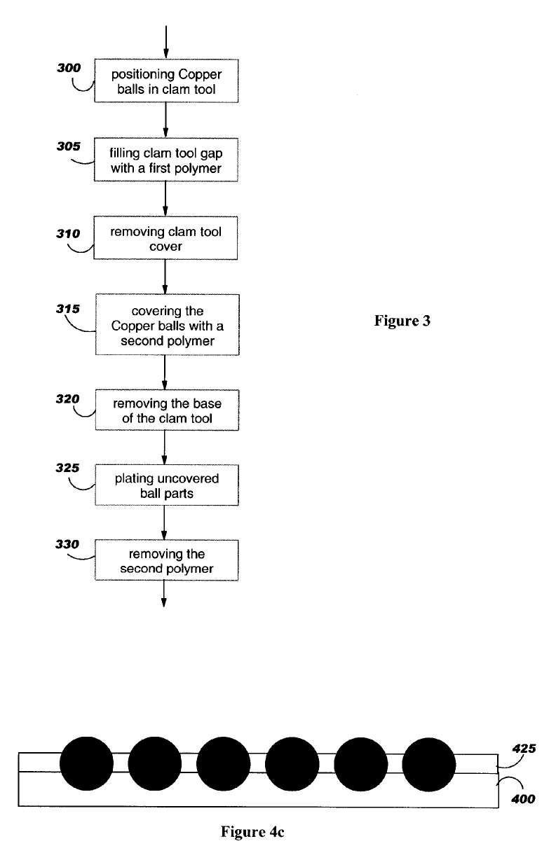

FIG. 3 depicts an algorithm illustrating the main steps of the method for manufacturing half plated balls. In this example, the method is based upon the use of Copper balls however, it must be understood that these balls can be made of other materials and plated with Copper or any other solderable material. Still for sake of illustration, it is assumed that diameter of balls may range between about 0.2 and 1.2 mm, for example approximately equal to 0.9 mm, one of the diameters in compliance with international industry standards, i.e. JEDEC (JEDEC Solid State Technology Association once known as the Joint Electron Device Engineering Council) defines accepted spheres diameters in its Solid State Product Outlines for plastic and ceramic packages (0.4, 0.5, 0.6, 0.762, and 0.9 mm). Naturally, a tolerance is given for each predefined diameter. For example, concerning diameter 0.6 mm, the minimum diameter can be 0.5 mm and the maximum diameter can be 0.7 mm, concerning diameter 0.762 mm, the minimum diameter can be 0.6 mm and the maximum diameter can be 0.9 mm, and concerning diameter 0.4 mm, the minimum diameter can be 0.35 mm and the maximum diameter can be 0.45 mm.

The first step (step 300) consists in positioning the Copper Balls in a clam tool comprising two parts, a lower part, also referred to as clam tool base, and an upper part, also referred to as clam tool cover. The lower and upper parts comprise aligned cavities, or recesses, arranged on the inner planar surface of each clam tool part in such a way that, when Copper balls are positioned in the recesses, the lower and upper parts are not in contact. In a preferred embodiment, the gap between inner planar surface of each clam tool parts is between about 0.15 mm and 0.6 mm, and a preferred value is approximately 0.30 mm i.e., 33 percent of the diameter of the ball. The gap between the clam tool parts must be large enough for injecting polymer but smaller than ball diameter so that a part of the ball is positioned in a recess of each clam tool part. Practically, the gap between the clam tool parts is chosen in the range of 15 to 75 percent of the diameter of the ball. Still in a preferred embodiment, the clam tool parts are made of fine grain graphite.

The positioning of the recesses formed in the clam tool parts is not important, the only requirement is that recesses of both clam tool parts are aligned. However, for improving the manufacturing process, recesses are preferably disposed according to the final disposition of half plated balls on the modules thus allowing a direct transfer when being soldered as discussed hereunder. Naturally, each clam tool part can comprise recesses corresponding to several modules.

Then, the inside gaps between the lower and upper clam tool parts i.e., the clearance areas through the Copper balls, are filled e.g., by injection, with a first polymer chemical solution (step 305). Examples of such a polymer chemical solution includes, but are not limited to, an epoxy, polyester, cyanate ester, bismaleimide triazine, benzo-cyclobutene, poly-phenilene ether, annylated poly-phenilene ether, polynorborene, liquid crystal polymer (LCP), poly-tetra-fluoro-ethylene, polyimide, or resinous material, and mixture thereof, as it is conventionally known mixed with a cathalyst, and a filler, and possibly with other additives to influence specific properties. After the polymerization of the first polymer chemical solution, the cover, or upper clam tool part, is removed (step 310) and the top side of the Copper balls is fully covered with a second polymer (step 315). The second polymer can be one of the temporary protection masks used in plating processes and based on natural acrylic latex, or chlorine-free polyolefin-based plastisol or organosol, or plastisol composition comprising polyvinyl chloride, a plasticizer, a stabilizer and highly crosslinked nitrile rubber. Furthermore, other polymers using specifically selected additive as releasing agent can be used such as epoxy, polyester, cyanate ester, bismaleimide triazine, benzo-cyclobutene, poly-phenilene ether, annylated poly-phenilene ether, polynorborene, liquid crystal polymer (LCP), poly-tetra-fluoro-ethylene, polyimide or resinous material, and mixture thereof, as it is conventionally known mixed with a cathalyst and a filler.

After the polymerization of the second polymer, the base of the clam tool is removed (step 320) and the bottom side of the Copper balls that are not caught by the first and second polymer material is plated with a noble metal (step 325). As mentioned above, a preferred embodiment comprises plating Nickel and then Gold or Palladium.

When the Copper balls are half or partially plated, the second polymer is removed (step 330) using, for example in the case of temporary protection mask based on natural acrylic latex, a peeling action separating the two films. A further selective stripping methodology can be the combination of polymers utilizing different stripping chemistries being soluble in alkali, acidic, or solvent baths. Therefore, at the end of the process, the half plated Copper balls are caught in a thin polymer layer. All the half plated Copper balls are positioned in the same direction i.e., the parts that are on one side of the thin polymer layer are made of or plated with solderable material while the parts that are on the other side of the thin polymer layer are plated with noble metal.

A partial replication of the aforementioned steps may allow proceeding with different platings of the base metal spheres delivering a final product with a multiple metal interface finishings along the sphere surface.

The thin polymer layer, or foil, embedding oriented half plated Copper balls presents some advantages for positioning and soldering balls on modules by maintaining orientation and precise organization of the plated spheres in manufacturing operation, as illustrated on FIG. 5.

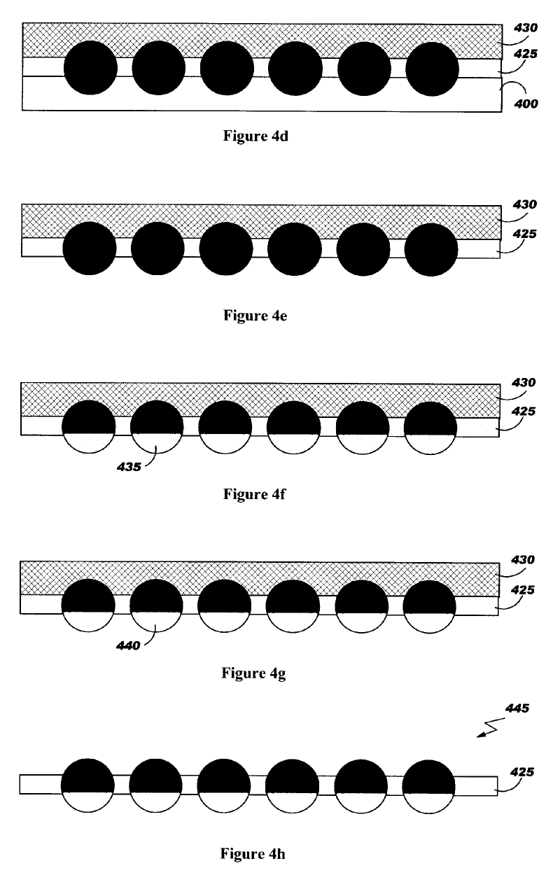

FIGS. 4a to 4h illustrate the steps of the method according to the invention for manufacturing half plated balls shown on FIG. 3. FIG. 4a shows the lower part (400) of a clam tool, or clam tool base, and the upper part (405), or clam tool cover. As illustrated, lower and upper parts 400 and 405 comprise recesses wherein Copper balls, generically referred to as 410-j, can be positioned. For sake of illustration, a couple of corresponding recesses (415-k and 420-k) do not hold a Copper ball.

FIG. 4b depicts the clam tool holding Copper balls, after the first polymer chemical solution 425 has been injected in the gap formed between the clam tool parts 400 and 405 as described by reference to step 305. FIG. 4c shows the same when clam tool cover 405 is removed after the polymerization of the first polymer chemical solution.

FIG. 4d illustrates the step of covering the Copper balls with the second polymer 430 (step 31 5) and FIG. 4e depicts the same when the base of the clam tool (400) is removed after the polymerization of the second polymer.

FIG. 4f shows the plating of the bottom side of the Copper balls that is not caught by the polymer material, with Nickel 435. As mentioned above, this step is not required with new Gold plating technology. FIG. 4g depicts the plating of the same Copper ball parts i.e., the bottom side of each of the Copper balls that is not caught by the polymer material, with Gold 440. The Gold is plated directly on the Copper ball or on the Nickel layer, according to technology now known or developed in the future.

Finally, FIG. 4h illustrates the resulting thin polymer layer 445, or foil, embedding oriented half plated Copper balls.

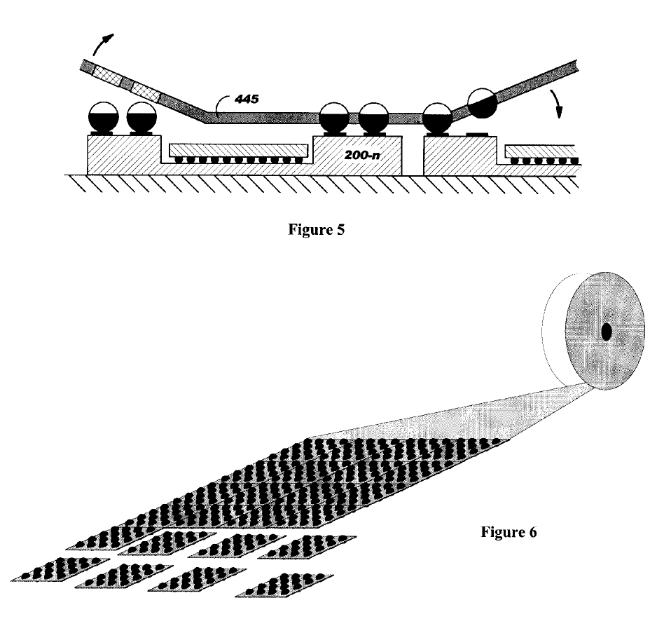

FIG. 5 depicts an example of using polymer layer 445 embedding half plated balls. As shown, such soft foil can be used directly to position the balls on the electronic modules, generically referred to as 200-n, the half plated balls being well oriented. When positioned, the balls are soldered according to standard soldering process i.e., by a solder alloy deposited between the balls and the corresponding plurality of lands of the PCB. Then, the foil can be peeled away as shown on the left, leaving the balls in place. FIG. 6 shows an example of pre-cut portions of soft foil embedding oriented half plated balls, obtained from a tape feeding reel.

Screen printing of large arrays of matrixes is often used on high mass production of low cost module devices. However, since the areas involved in the solder paste screen printing are large and the products are low cost, it should be required to accept a high variability in the quantity and characteristics of solder paste deposited by the screen printing operation. To specifically address such a low cost mass production implementation, a solder wetting flow limiting barrier is preferably embedded into the coating manufacturing of the balls. This is done by inserting an oxidation step of the copper spheres prior to proceed with the resin encapsulation. This extra step delivers a better control of the self positioning of the coated metal spheres during soldering operation, especially when used with a combination of screened solder paste deposition over the chip carrier substrate pads.

Once the spheres are released from the polymer foil, and are in touch with oversized deposits of wet solder paste, there is the possibility that the wetting forces of the liquid part of the solder paste exercise some rotational effects against the spheres. As a consequence, the spheres can lose their original orientation “as placed”. Furthermore, if a similar wetting phenomena exists along the whole surface of the freed spheres during the soldering operation i.e., all different metallizations are wettable by the liquid solder, they may continue to rotate along their own center during solder reflow, completely losing their orientation.

To allow mass production and a self-correcting process of the sphere orientation it is possible to create a precise three level surface finishing where the two ends i.e., exposed solderable copper and gold portions, are separated by a central region of oxidized copper that is not readily wettable by solder alloys without a strong support of decapping agents such as organic fluxes that are not provided into the process. The wetting forces of the melted alloy drive the same alloy to embrace the total wettable surface area (exposed and not oxidized copper area) achieving a minimum energy configuration that results into a spatial self correcting rotational re-alignment of the spheres. The copper oxidized portion very effectively stops the travel of the solder alloys along the opposite end of the spheres avoiding any possible contact between the solders and the different metallization i.e., tin and gold.

The partial oxidation of the spheres may be obtained after step 300 of FIG. 3 by exposing the obtained stack of clams and spheres to an oxidizing atmosphere i.e., an adapted couple of temperature and air/oxygen, for a short cycle. Spheres can also undergo to an oxidation step prior to being used within the flow shown in FIG. 3. Then the process continues as previously explained with step 305, embedding the center of the oxidized spheres in a polymer material. The following plating process steps including in particular depositing nickel or other metals (step 325 of FIG. 3) comprises sub-steps that re-activate the copper surface prior to applying the new metal i.e., that remove oxides. Therefore the oxide layers of the two opposite sides of the spheres will be removed at different times (or at the same time, revisiting accordingly the flow presented in FIG. 3), leaving the central portion of the spheres with its own oxide barrier in place since it is protected by the polymer sheet. Once extracted from the polymer foil, the spheres have three metal surface finishings, allowing for an improved positioning of the spheres as described above.

Naturally, in order to satisfy local and specific requirements, a person skilled in the art may apply to the solution described above many modifications and alterations all of which, however, are included within the scope of protection of the invention as defined by the following claims.

What is claimed is:

1. A method for partially plating a ball, the method comprising the steps of: providing a clam tool comprising two parts, each part comprising a respective recess configured to cover a portion of said ball wherein if said respective recesses of said two parts are aligned to form a cavity, the size of said cavity is such that when said ball is positioned within said cavity a gap is formed between said two parts;
positioning said ball in said cavity;
forming a first polymerized polymer in said;
removing one of said two parts to expose a first uncovered part of said ball;
covering said first uncovered part of said ball with a second polymerized polymer;
removing the second one of said two parts to expose a second uncovered part of said ball; and
plating said second uncovered part of said ball.

2. The method of claim 1 wherein forming said first polymerized polymer comprises injecting a first polymer solution into said gap and polymerizing said first polymer solution.

3. The method of claim 2 wherein said first polymer solution comprises a material selected from the group consisting of polyester, cyanate ester, bismaleimide triazine, benzo-cyclobutene, poly-phenilene ether, annylated poly-phenilene ether, polynorborene, liquid crystal polymer (LCP), poly-tetra-fluoro-ethylene, polyimide, resinous material, and a mixture thereof.

4. The method of claim 1 wherein said second polymer comprises a material selected from the group consisting of a natural acrylic latex, a chlorine-free polyolefin-based plastisol, a chlorine-free polyolefin-based organosol, a plastisol composition and a protection mask used in plating processes.

5. The method of claim 1 further comprising, after said step of positioning said ball in said cavity, exposing said two parts having said ball positioned therein to an oxydizing atmosphere prior to forming said first polymerized polymer.

6. The method of claim 1 further comprising the step of removing said second polymerized polymer.

7. The method of claim 1 wherein said step of plating said second uncovered part of said ball comprises the steps of plating said second uncovered part of said ball with a noble metal.

8. The method of claim 7 wherein said noble metal is selected from the group consisting of gold and palladium.

9. The method of claim 7 further comprising the step of plating said second uncovered part of said ball with nickel prior to said plating with said noble metal.

10. The method of claim 1 wherein said first polymerized polymer forms a soft foil.

11. The method of claim 1 wherein said ball comprises a solderable material.

12. The method of claim 11 wherein said solderable material is copper.

13. The method of claim 1 wherein the diameter of said ball is comprised between 0.2 and 1.2 mm.

14. The method of claim 1 wherein the diameter of said ball is chosen among 0.4, 0.5, 0.6, 0.762, and 0.9 mm.

15. The method of claim 1 wherein said gap between said two parts when said ball is positioned within said cavity is in the range between 15 and 75 percent of the diameter of said ball.

16. The method of claim 1 wherein said gap between said two parts when said ball is positioned within said cavity is approximately equal to 33 percent of the diameter of said ball.

17. The method of claim 10 wherein each of said two parts comprise a corresponding plurality of recesses, and said method further comprises positioning a plurality of balls in cavities formed by said corresponding plurality of recesses, so that after said step of plating, said plurality of balls are embedded in said soft foil.

18. The method of claim 17 further comprising positioning said plurality of balls on an electronic module using said soft foil having said plurality of balls embedded therein.

19. The method of claim 18 further comprising soldering said plurality of balls to said electronic module and removing said soft foil while leaving said plurality of balls on said electronic module.

20. The method of claim 18 wherein said soft foil having said plurality of balls embedded therein are deployed on a tape feeding reel, and wherein said positioning said plurality of balls on an electronic module further comprises obtaining said soft foil from said tape feeding reel.
